(19) United States
(12) Patent Application Publication
(10) Pub. No.: US 2026/0211063 A1
(43) Pub. Date: Jul. 23, 2026

(54) SYSTEM AND METHOD FOR TRACING AND IMAGING MAGNETIC FIELD CONFIGURATION OF STELLARATOR

(71) Applicant: SOUTHWEST JIAOTONG UNIVERSITY, Chengdu (CN)

(72) Inventors: Haifeng LIU, Chengdu (CN); Xirui LIU, Chengdu (CN); Xiaofeng ZHENG, Chengdu (CN); Yuhong XU, Chengdu (CN); Jun CHENG, Chengdu (CN); Xianqu WANG, Chengdu (CN); Jie HUANG, Chengdu (CN); Xin ZHANG, Chengdu (CN); Hai LIU, Chengdu (CN); Junfeng SHEN, Chengdu (CN); Xianghui CHANG, Chengdu (CN); Jun HU, Chengdu (CN); Heng LAN, Chengdu (CN)

(21) Appl. No.: 19/572,237

(22) Filed: Mar. 19, 2026

(30) Foreign Application Priority Data
Dec. 29, 2025 (CN) 202512009968.1

(51) Int. Cl. G01R 33/10; G01R 33/032; G21B 1/05

(52) U.S. Cl. CPC G01R 33/10; G01R 33/032; G21B 1/055

(57) ABSTRACT

A system for tracing and imaging magnetic field configuration of a stellarator, including an electron beam emission and adjusting unit, a dynamic fluorescence imaging unit and an image acquiring unit. The stellarator includes a vacuum chamber and a three-dimensional vacuum magnetic field formed in the vacuum chamber. The electron beam emission and adjusting unit is configured to emit an electron beam. The dynamic fluorescence imaging unit includes a fluorescent grid and a grid drive mechanism. The fluorescent grid is arranged at a Poincaré surface of section located in the three-dimensional vacuum magnetic field. The grid drive mechanism is configured to drive the fluorescent grid to periodically reciprocate. The image acquiring unit is configured to image the fluorescent grid. A method for measuring the magnetic field configuration based on the system is also provided.

### CROSS-REFERENCE TO RELATED APPLICATIONS

This application claims the benefit of priority from Chinese Patent Application No. 202512009968.1, filed on Dec. 29, 2025. The content of the aforementioned application, including any intervening amendments thereto, is incorporated herein by reference in its entirety.

### TECHNICAL FIELD

This application relates to stellarators, and more particularly to a system and method for tracing and imaging magnetic field configuration of a stellarator.

### BACKGROUND

The content described below is related to background information of this disclosure, and are not intended to limit the prior art.

Currently, the magnetic confinement nuclear fusion devices are predominated by tokamaks and stellarators. The stellarators directly generate a three-dimensional vacuum magnetic field with rotational transform through external and complicated three-dimensional modular coils, so as to confine plasma without requiring plasma current, resulting in a superior advantage over the tokamaks in terms of steady-state operation.

The configuration of the three-dimensional vacuum magnetic field of the stellarators exhibits high three-dimensional helical twist and non-axisymmetry, causing extremely high requirements for fabrication and installation accuracy. In actual engineering, the magnetic field configuration is prone to deviate from a theoretical design thereof due to a series of factors such as coil manufacturing tolerance, installation deviation (e.g., Z-axis displacement) and deformation caused by electromagnetic force after power-on, thereby generating magnetic islands or even randomization of magnetic surface. As a consequence, after the stellarator is established and before conducting plasma experiment, it is crucial to conduct high-precision measurement and verification of the configuration of the three-dimensional vacuum magnetic field.

### SUMMARY

In view of this, a first objective of the present disclosure is to provide a system for tracing and imaging magnetic field configuration of a stellarator, so as to conduct high-precision measurement and verification of configuration of three-dimensional vacuum magnetic field generated by a stellarator.

A second objective of the present disclosure is to provide a method for measuring a three-dimensional vacuum magnetic field of the stellarator, which is performed based on the aforementioned system, so as to conduct the high-precision measurement and verification of the configuration of the three-dimensional vacuum magnetic field generated by the stellarator.

In order to achieve the above objectives, the following technical solutions of the present disclosure are adopted.

In a first aspect, the present disclosure provides a system for tracing and imaging magnetic field configuration of a stellarator.

A system for tracing and imaging magnetic field configuration of a stellarator, the stellarator comprising a vacuum chamber and a three-dimensional vacuum magnetic field formed in the vacuum chamber, and the system comprising:
an electron beam emission and adjusting unit;
a dynamic fluorescence imaging unit; and
an image acquiring unit;
wherein the electron beam emission and adjusting unit is configured to emit an electron beam in the three-dimensional vacuum magnetic field, and to adjust an emission position and an emission direction of the electron beam to allow the electron beam to move along a magnetic induction line at the emission position;
the dynamic fluorescence imaging unit comprises a fluorescent grid and a grid drive mechanism; the fluorescent grid is arranged at a Poincaré surface of section located in the three-dimensional vacuum magnetic field; and the grid drive mechanism is configured to drive the fluorescent grid to periodically reciprocate in a plane where the Poincaré surface of section is located;
the image acquiring unit is configured to image the fluorescent grid, and is configured to have a long-exposure integration imaging mode; and
in response to a case that the fluorescent grid is driven by the grid drive mechanism to periodically reciprocate, the image acquiring unit is configured to perform an integration imaging with an exposure time that covers at least one reciprocating cycle of the fluorescent grid, so as to obtain a magnetic surface trajectory image generated by the electron beam on the fluorescent grid.

In some embodiments, the electron beam emission and adjusting unit comprises an electron gun configured for emitting the electron beam; and the electron gun has an emission energy of 1-250 eV, a beam spot current of 1.0-7.0 mA and an exit aperture of 1.0 mm.

In some embodiments, the fluorescent grid has an optical transparency greater than 95%.

In some embodiments, the fluorescent grid comprises a plurality of grid cells; and each of the plurality of grid cells has a size of 20 mm×20 mm.

In some embodiments, a stroke amplitude of the fluorescent grid is not less than a diagonal length of each of a plurality of grid cells of the fluorescent grid.

In some embodiments, the grid drive mechanism is arranged outside the vacuum chamber; the grid drive mechanism comprises a linear actuator, a movable base, a sealing corrugated pipe and a connecting part;
the movable base is configured to reciprocate along a moving direction of the fluorescent grid under the drive of the linear actuator;
a first end of the sealing corrugated pipe is sealedly connected to the movable base, and a second end of the sealing corrugated pipe is sealedly connected to an outer wall of the vacuum chamber; and
a first end of the connecting part is connected to the fluorescent grid, and a second end of the connecting part is connected to the movable base; and a portion of the connecting part located outside the vacuum chamber is accommodated within the sealing corrugated pipe.

In some embodiments, the image acquiring unit is a Peltier-cooled charge coupled device (CCD) camera.

In a second aspect, the present disclosure provides a method for measuring a three-dimensional vacuum magnetic field of the stellarator, where the method is performed based on the aforementioned system, and the method comprises:
(S1) controlling the electron beam emission and adjusting unit to emit the electron beam from a preset emission position to a radial position located in the three-dimensional vacuum magnetic field of the stellarator;
(S2) adjusting an emission energy and a beam spot current of the electron beam to obtain a plurality of fluorescence images on the fluorescent grid under different parameter combinations; and selecting a parameter combination from the different parameter combinations as a target operation parameter based on brightness and definition of the plurality of fluorescence images, wherein the target operation parameter comprises a target emission energy and a target beam spot current;
(S3) controlling the electron beam emission and adjusting unit to emit the electron beam with the target operation parameter from the preset emission position to the radial position; controlling the grid drive mechanism to drive the fluorescent grid to periodically reciprocate at a preset speed; and controlling the image acquiring unit to perform the integration imaging with the exposure time that covers the at least one reciprocating cycle of the fluorescent grid, so as to obtain the magnetic surface trajectory image at the radial position; and
(S4) maintaining parameters of the three-dimensional vacuum magnetic field constant; controlling the electron beam emission and adjusting unit to move from the preset emission position along a radial direction of the three-dimensional vacuum magnetic field at a preset step size to a series of new radial positions; and repeating steps (S1-S3) at each of the series of new radial positions to obtain a plurality of magnetic surface trajectory images that are nested.

In some embodiments, the method further comprises:
(S5) processing the plurality of magnetic surface trajectory images to extract central coordinates of a plurality of bright spots in each of the plurality of magnetic surface trajectory images, so as to reconstruct a measured magnetic surface profile of the three-dimensional vacuum magnetic field; and comparing the measured magnetic surface profile with a theoretical magnetic surface profile of the three-dimensional vacuum magnetic field at the same Poincaré surface of section.

In some embodiments, step (S1) further comprises:
adjusting the emission direction of the electron beam to minimize a Larmor radius thereof, so as to allow the electron beam to generate a fluorescence signal with a convergent, closed and clear trajectory on the fluorescent grid.

Compared to the prior art, the present disclosure at least has the following beneficial effects.

By innovatively driving the fluorescent grid to periodically reciprocate and synchronizing it with the image acquiring unit, the present disclosure not only enables the measurement of the magnetic field configuration in the three-dimensional vacuum magnetic field, but also eliminates the inherent imaging dead zones of static grids. This approach yields more precise and continuous magnetic surface trajectory images. Consequently, it provides more reliable support for the accurate verification of the configuration of the three-dimensional vacuum magnetic field of the stellarator.

### BRIEF DESCRIPTION OF THE DRAWINGS

FIG. 1 schematically shows a principle of a system for tracing and imaging magnetic field configuration of a stellarator according to an embodiment of the present disclosure;

FIG. 2 schematically shows an electron beam emission and adjusting unit according to an embodiment of the present disclosure (in operation); and

FIG. 3 schematically shows a dynamic fluorescence imaging unit according to an embodiment of the present disclosure.

In the figures: 10—electron beam emission and adjusting unit; 11—electron gun; 12—electron gun drive device; 20—dynamic fluorescence imaging unit; 21—fluorescent grid; 22—grid drive mechanism; 221—linear actuator; 222—movable base; 223—sealing corrugated pipe; 224—connecting part; 225—sealing flange; and 30—image acquiring unit.

### DETAILED DESCRIPTION OF EMBODIMENTS

In order to make the purpose, technical solutions and advantages of the present disclosure clearer, the technical solutions of the present disclosure will be clearly and completely described below with reference to the embodiments. The same labels in the accompanying drawings of the present disclosure correspond to the same components. It should be noted that described below are merely some embodiments of the present disclosure, not all embodiments. Based on the embodiments in the present disclosure, all other embodiments obtained by those of ordinary skill in the art without paying creative labor shall fall within the scope of the present disclosure.

Compared to the embodiments disclosed in the accompanying figures, feasible implementations within the protection scope of the present disclosure can have fewer components, include additional components not shown in the accompanying drawings, adopt different components, arrange components differently, or feature different interconnections between components, among other variations. Furthermore, two or more components shown in the accompanying drawings can be combined into a single component, or a single component shown in the accompanying drawings can be divided into multiple separate components.

For technical or scientific terms not specifically defined herein, they should be given the meaning that those skilled in the art can give them, according to the disclosure content and context. Furthermore, the terms “first” and “second” are only for descriptive purposes to distinguish the different components, and should not be understood as indicating or implying the sequence, the quantity or the relative importance of the technical features involved.

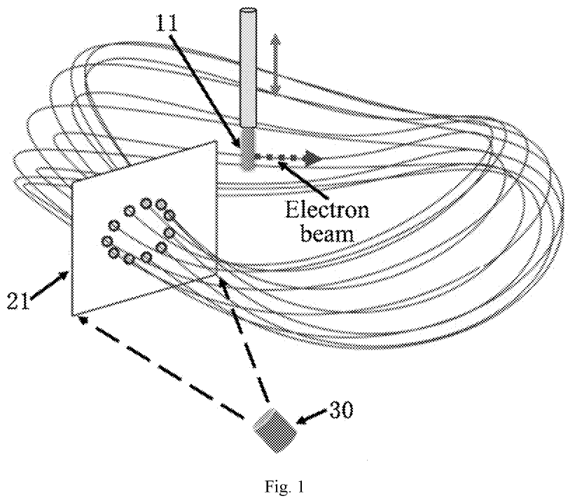

Referring to FIGS. 1-3, the present disclosure provides a system for tracing and imaging magnetic field configuration of a stellarator.

In some embodiments, the stellarator includes a vacuum chamber and a three-dimensional magnetic field formed in the vacuum chamber. The system provided herein is applied for high-precision measurement of the configuration of the three-dimensional vacuum magnetic field.

In some embodiments, the system includes an electron beam emission and adjusting unit 10, a dynamic fluorescence imaging unit 20 and an image acquiring unit 30.

In some embodiments, the electron beam emission and adjusting unit 10 is configured to emit an electron beam under conditions of high vacuum (10⁻⁵ Pa) and strong magnetic field in the three-dimensional vacuum magnetic field of the stellarator, and to adjust an emission position and an emission direction of the electron beam, so as to allow the electron beam to move along a magnetic induction line (i.e., a red line in FIG. 1) at the emission position.

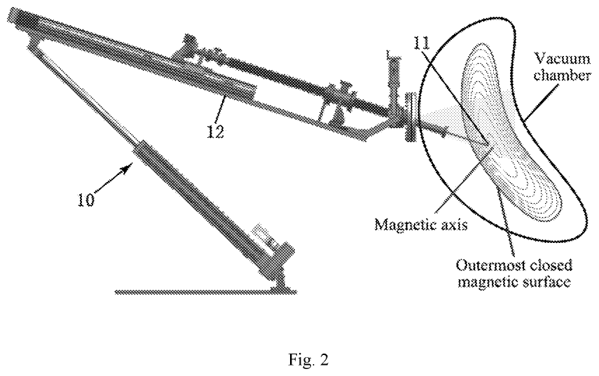

Referring to FIG. 2, the electron beam emission and adjusting unit 10 includes an electron gun 11 and an electron gun drive device 12. The electron gun 11 is configured to emit the electron beam in the three-dimensional vacuum magnetic field, and is arranged on an output end of the electron gun drive device 12. The electron gun drive device 12 is configured to drive the electron gun 11 to generate radial displacement, poloidal displacement and axial rotation, so as to adjust an emission position and an emission direction of the electron beam emitted from the electron gun 11.

In some embodiments, the emission position of the electron beam is adjusted through the radial displacement and the poloidal displacement. The electron gun 11 is allowed to reach different radial positions of the three-dimensional vacuum magnetic field through the radial displacement, so as to enable to measure magnetic surfaces at the different radial positions. A vertical elevation angle of the electron gun 11 is adjusted through the poloidal displacement, so that the electron beam is accurately emitted to a spatial position where a magnetic axis of the three-dimensional vacuum magnetic field exits. A spin angle of the electron gun 11 is adjusted through the axial rotation to adjust the emission direction of the electron beam, such that the emission direction of the electron beam is as parallel as possible to the magnetic induction line at the emission position during actual measurement, so as to minimize a Larmor radius of the electron beam. By means of this, a vertical velocity component of the electron beam is minimized to eliminate the blurring of light spot caused by helical motion of the electron beam, which is conductive to generate a fluorescence signal with a convergent, closed and clearer trajectory on the fluorescent grid 21 described below.

In order to enable the electron gun 11 to generate the above various motions while avoiding the electron gun drive device 12 occupying the space in the vacuum chamber and damaging the vacuum degree inside the vacuum chamber, the structure and working principle of the electron beam emission and adjusting unit 10 disclosed herein can be referred to the relevant description in Chinese patent No. 118352099B (i.e., multi-degree-of-freedom electron gun drive device for quasi-ring symmetric stellarator). For the sake of brevity, there is no elaboration.

Based on Chinese patent No. 118352099B, the electron gun 11 disclosed herein adopts miniaturized design to decrease a sectional size of electron gun 11 to the greatest extent, so as to prevent the electron beam from striking a back of the electron gun 11 after completing one toroidal revolution along the magnetic induction line. Consequently, it ensures that the electron beam can travel along the magnetic induction line for multiple revolutions, guaranteeing the feasibility of multi-turn measurements.

In some embodiments, the electron gun 11 is provided with a barium tungsten alloy filament. The electron gun 11 has an emission energy of 1-250 eV and a beam spot current of 1.0-7.0 mA. The electron gun 11 is continuously adjustable in terms of the emission energy and the beam spot current. The electron gun 11 has an exit aperture of 1.0 mm. These parameters of the electron gun 11 are further constrained to enable the electron gun 11 to emit the electron beam with sufficient emission energy, sufficient beam spot current, and a beam spot diameter that meets the measurement requirements.

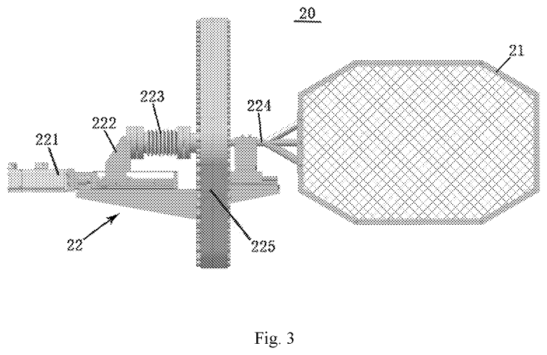

In some embodiments, the dynamic fluorescence imaging unit 20 is adopted as a crucial innovation of this disclosure. Referring to FIG. 1 and FIG. 3, the dynamic fluorescence imaging unit 20 includes the fluorescent grid 21 and a grid drive mechanism 22. The fluorescent grid 21 is arranged at a Poincaré surface of section located in the three-dimensional vacuum magnetic field. The grid drive mechanism 22 is configured to drive the fluorescent grid 21 to periodically reciprocate in a plane where the Poincaré surface of section is located, indicating that the fluorescent grid 21 is driven to periodically reciprocate along a direction perpendicular to the magnetic axis of the three-dimensional vacuum magnetic field.

In some embodiments, the fluorescent grid 21 is configured as an imaging target, and is arranged at the Poincaré surface of section located in the three-dimensional vacuum magnetic field. During the motion of the electron beam along the magnetic induction line, some electrons in the electron beam are configured to strike gridlines of the fluorescent gird 21 to generate a fluorescence signal as a magnetic surface trajectory, and the rest electrons in the electron beam are configured to traverse grid cells of the fluorescent grid 21 and continuously move along the magnetic induction line.

In some embodiments, the fluorescent grid 21 includes a main body, a plurality of grid cells and a plurality of gridlines. The main body is configured as a uniform stainless-steel grid coated with a fluorescent material (such as zinc oxide). Each of the plurality of grid cells has a size of 20 mm×20 mm. Each of the plurality of gridlines are superfine. By means of this, the fluorescent grid 21 exhibits a high optical transparency to allow most electrons in the electron beam to traverse the fluorescent grid 21 and continuously move along the magnetic induction line, thereby enabling multi-turn imaging.

In some embodiments, the fluorescent grid 21 has an optical transparency greater than 95%.

In the prior art, the fluorescent grid 21 is set to be static in the system for tracing and imaging the magnetic field configuration of the stellarator. Each of the plurality of grid cells of the fluorescent grid 21 is configured as a void structure. Consequently, when the electron beam traverses the static fluorescent grid 21, electrons at some positions will always strike the plurality of gridlines of the fluorescent grid 21, while electrons at other positions will never strike the plurality of gridlines of the fluorescent grid 21, thereby obtaining a magnetic surface trajectory image that is a discontinuous trajectory composed of a series of discrete light spots, resulting in many imaging dead zones and affecting the integrity and measurement precision of magnetic surface contour.

In order to address the above problems in the prior art, the grid drive mechanism 22 is introduced into the embodiments of the present disclosure.

In some embodiments, the grid drive mechanism 22 is configured to drive the fluorescent grid 21 to periodically reciprocate, so that the plurality of gridlines of the fluorescent grid 21 are allowed to traverse and cover the areas that originally correspond to the void structures of the plurality of grid cells. Therefore, when the electron beam undergoes multi-turn motion along the magnetic induction line and traverses the fluorescent grid 21 for many times, electrons at all potions in the electron beam can strike the plurality of gridlines of the fluorescent grid 21 to generate fluorescence signals. Afterward, all fluorescence signals generated by the electron beam are continuously recorded and integrated over time by the image acquiring unit 30, so as to enable the image acquiring unit 30 to obtain more continuous and complete magnetic surface trajectory images, thereby improving the measurement precision.

In some embodiments, a stroke amplitude of the fluorescent grid 21 is not less than a diagonal length of each of a plurality of grid cells of the fluorescent grid 21, which indicates that one-way stroke amplitude of the fluorescent grid 21 from an initial position to a limit position is not less than the diagonal length of each of the plurality of grid cells. By means of this, the plurality of gridlines of the fluorescent grid 21 are allowed to traverse and cover the areas that originally correspond to the void structures of the plurality of grid cells.

According to the aforementioned description, the image acquiring unit 30 is configured to image the fluorescent grid 21, and is configured to have a long-exposure integration imaging mode.

In some embodiments, the image acquiring unit 30 is a Peltier-cooled charge coupled device (CCD) camera arranged outside the vacuum chamber. The Peltier-cooled CCD camera is configured to be operated at −45° C., and effectively suppress thermal noise. Moreover, the Peltier-cooled CCD camera has a quantum efficiency highly reaching to 95%, and supports long-exposure integration imaging mode ranging from 1 s to 5 min. Combined with a 13 μm pixel size, the Peltier-cooled CCD camera can capture weak fluorescence signals, which is conducive to improving the precision of the magnetic surface trajectory image.

According to the aforementioned description, the system provided herein can achieve a breakthrough of continuous imaging without any imaging dead zones. The reason lies in another crucial innovation that the fluorescent grid 21 is allowed to cooperate with the image acquiring unit 30 based on the following methods. When the fluorescent grid 21 is driven to periodically reciprocate, the image acquiring unit 30 is configured to perform an integration imaging with an exposure time that covers at least one reciprocating cycle of the fluorescent grid 21, so as to obtain a magnetic surface trajectory image generated by the electron beam on the fluorescent grid 21.

In some embodiments, the at least one reciprocating cycle of the fluorescent grid 21 indicates that the exposure time is not less than a time required for the fluorescent grid 21 to finish the at least one reciprocating cycle.

In some embodiments, the cooperation between the fluorescent grid 21 and the image acquiring unit 30 is performed through the following steps.

When the image acquiring unit 30 undergoes a long-exposure process, the plurality of gridlines of the fluorescent grid 21 are allowed to traverse and cover the areas that originally correspond to the void structures of the plurality of grid cells during the reciprocating motion of the fluorescent grid 21. Meanwhile, an electron beam that is confined to the magnetic surface traverses the fluorescent grid 21 at the Poincaré surface of section for many times. With each traversal, some electrons in the electron beam strike the plurality of gridlines that are positioned there at that time, thereby generating the fluorescence signal. Since the exposure time of the image acquiring unit 30 fully covers the at least one reciprocating cycle of the fluorescent grid 21, all fluorescence signals generated by the electron beam are continuously received and temporally integrated by the image acquiring unit 30 throughout the exposure time. Ultimately, in an image generated by image acquiring unit 30, all fluorescence signals are fused into a continuous and complete bright line. The bright line is the accurate and continuous magnetic surface trajectory image of the magnetic surface at the Poincaré surface of section, that is, a single circular closed trajectory located in the vacuum chamber in FIG. 2.

By innovatively driving the fluorescent grid 21 to periodically reciprocate and synchronizing it with the image acquiring unit 30, the present disclosure not only enables the measurement of the magnetic field configuration in the three-dimensional vacuum magnetic field, but also eliminates the inherent imaging dead zones of static grids. This approach yields more precise and continuous magnetic surface trajectory images. Consequently, it provides more reliable support for the accurate verification of the configuration of the three-dimensional vacuum magnetic field of the stellarator.

In some embodiments, the grid drive mechanism 22 is arranged outside the vacuum chamber to prevent it from occupying the confined space in the vacuum chamber. In order to avoid damaging the vacuum degree of the vacuum chamber, the grid drive mechanism 22 adopts the following configurations on this basis.

Referring to FIG. 3, the grid drive mechanism 22 includes a linear actuator 221; a movable base 222, a sealing corrugated pipe 223 and a connecting part 224.

In some embodiments, the movable base 222 is movably arranged at an exterior of the vacuum chamber. The movable base 222 is driven to reciprocate along a moving direction of the fluorescent grid 21 under the drive of the linear actuator 221. A first end of the sealing corrugated pipe 223 is seadledly connected to the movable base 222, and a second of the sealing corrugated pipe 223 is seadledly connected to an outer wall of the vacuum chamber via a sealing flange 225. A passage arranged inside the sealing flange 225 is connected to the vacuum chamber.

In some embodiments, a first end of the connecting part 224 is connected to the fluorescent grid 21, and a second end of the connecting part 224 is connected to the movable base 222. Moreover, a portion of the connecting part 224 located outside the vacuum chamber is accommodated within the sealing corrugated pipe 223, indicating that the second end of the connecting part 224 is configured to pass through the passage arranged inside the sealing flange 225, extend into the sealing corrugated pipe 223 and be connected to the movable base 222.

Based on the above arrangements, when the linear actuator 221 drives the movable base 222 to reciprocate, the movable base 222 drives the fluorescent grid 21 to synchronously reciprocate via the connecting part 224, such that the sealing corrugated pipe 223 adapts to the reciprocation of the movable base 222 by extending and retracting. The grid drive mechanism 22 with such a structure not only drives the fluorescent grid 21 to reciprocate, but also effectively avoids damaging the vacuum degree of vacuum chamber through the dynamic seal of the sealing corrugated pipe 223.

In some preferable embodiments, the linear actuator 221 is an electric-powered push rod driven by a servo motor to enhance the motion accuracy of the fluorescent grid 21 as much as possible.

In some embodiments, the linear actuator 221 is configured to drive the fluorescent grid 21 to move at 0-4 mm/s.

In another aspect, the present disclosure provides a method for measuring the three-dimensional vacuum magnetic field of the stellarator, where the method is performed based on the aforementioned system, and is performed through the following steps.
(S1) The vacuum degree of the vacuum chamber is reduced to 10⁻⁵ Pa. Current is introduced into the three-dimensional modular coils of the stellarator to establish a steady-state three-dimensional vacuum magnetic field in the vacuum chamber.

The electron beam emission and adjusting unit 10 is controlled to emit the electron beam from a preset emission position to a radial position located in the three-dimensional vacuum magnetic field of the stellarator. The emission position indicates that an emission terminal of the electron gun 11 is configured to align with a spatial position where the magnetic axis of the three-dimensional vacuum magnetic field exits by adjusting the radial position and poloidal position of the electron gun 11.

In this case, to ensure that the electron beam emitted by the electron gun 11 can smoothly move along the magnetic induction line at the radial position without diverging, step S1 further includes as follows. The emission direction of the electron beam is adjusted by driving the electron gun 11 to axially rotate, so that the emission direction of the electron beam is as parallel as possible to the magnetic induction line at the radial position, so as to minimize a Larmor radius thereof, and allow the electron beam to generate a fluorescence signal with a convergent, closed and clear trajectory on the fluorescent grid 21.
(S2) An emission energy and a beam spot current of the electron beam are adjusted to obtain a plurality of fluorescence images on the fluorescent grid 21 under different parameter combinations. A parameter combination is selected from the different parameter combinations as a target operation parameter based on brightness and definition of the plurality of fluorescence images, where the target operation parameter includes a target emission energy and a target beam spot current.

The standard for selecting the target operation parameter is that the divergence of the electron beam and the Larmor radius should be as small as possible on the premise of sufficient brightness (signal-to-noise ratio) of the plurality of fluorescence images, thereby balancing imaging visibility and spatial resolution. This further provides guarantee for the subsequent acquisition of magnetic surface trajectory images that are both bright enough and clear enough.
(S3) The electron beam emission and adjusting unit 10 is controlled to emit the electron beam with the target operation parameter from the preset emission position to the radial position, so as to allow the electron beam to move along the magnetic induction line at the radial position.

In this case, the grid drive mechanism 22 is controlled to drive the fluorescent grid 21 to periodically reciprocate at a preset speed. The image acquiring unit 30 is synchronously controlled to perform the integration imaging with the exposure time that covers the at least one reciprocating cycle of the fluorescent grid 21, so as to obtain the magnetic surface trajectory image at the radial position. According to the aforementioned description, the plurality of gridlines of the fluorescent grid 21 are allowed to traverse and cover the areas that originally correspond to the void structures of the plurality of grid cells, such that the image acquiring unit 30 obtains more continuous and complete magnetic surface trajectory image at the radial position.

In some embodiments, the grid drive mechanism 22 is configured to drive the fluorescent grid 21 to move at 4 mm/s.
(S4) Parameters of the three-dimensional vacuum magnetic field are maintained constant. The electron gun 10 of the electron beam emission and adjusting unit 10 is controlled to move from the preset emission position along a radial direction of the three-dimensional vacuum magnetic field at a preset step size to a series of new radial positions.

In some embodiments, the preset step size is 5 mm.

In some embodiments, steps (S1-S3) are repeated at each of the series of new radial positions to obtain a plurality of magnetic surface trajectory images that are nested.
(S5) The plurality of magnetic surface trajectory images obtained by the image acquiring unit 30 are processed to extract central coordinates of a plurality of bright spots in each of the plurality of magnetic surface trajectory images, so as to reconstruct a measured magnetic surface profile of the three-dimensional vacuum magnetic field.

The measured magnetic surface profile is compared with a theoretical magnetic surface profile of the three-dimensional vacuum magnetic field at the same Poincaré surface of section, so as to verify whether the magnetic field configuration of the three-dimensional vacuum magnetic field of the stellarator meets the design requirements.

Provided herein are some preferable embodiments of the present disclosure, and are not to intended to limit this disclosure. Any modifications, equivalent replacements and improvements made by those skilled in the art to this disclosure without departing from the spirit and principle of the present disclosure shall fall within the scope of the present disclosure defined by the appended claims.

What is claimed is:

1. A system for tracing and imaging magnetic field configuration of a stellarator, the stellarator comprising a vacuum chamber and a three-dimensional vacuum magnetic field formed in the vacuum chamber, and the system comprising:
an electron beam emission and adjusting unit;
a dynamic fluorescence imaging unit; and
an image acquiring unit;
wherein the electron beam emission and adjusting unit is configured to emit an electron beam in the three-dimensional vacuum magnetic field, and to adjust an emission position and an emission direction of the electron beam to allow the electron beam to move along a magnetic induction line at the emission position;
the dynamic fluorescence imaging unit comprises a fluorescent grid and a grid drive mechanism; the fluorescent grid is arranged at a Poincaré surface of section located in the three-dimensional vacuum magnetic field; and the grid drive mechanism is configured to drive the fluorescent grid to periodically reciprocate in a plane where the Poincaré surface of section is located;
the image acquiring unit is configured to image the fluorescent grid, and is configured to have a long-exposure integration imaging mode; and
in response to a case that the fluorescent grid is driven by the grid drive mechanism to periodically reciprocate, the image acquiring unit is configured to perform an integration imaging with an exposure time that covers at least one reciprocating cycle of the fluorescent grid, so as to obtain a magnetic surface trajectory image generated by the electron beam on the fluorescent grid.

2. The system of claim 1, wherein the electron beam emission and adjusting unit comprises an electron gun configured for emitting the electron beam; and the electron gun has an emission energy of 1-250 eV, a beam spot current of 1.0-7.0 mA and an exit aperture of 1.0 mm.

3. The system of claim 1, wherein the fluorescent grid has an optical transparency greater than 95%.

4. The system of claim 1, wherein the fluorescent grid comprises a plurality of grid cells; and each of the plurality of grid cells has a size of 20 mm×20 mm.

5. The system of claim 1, wherein a stroke amplitude of the fluorescent grid is not less than a diagonal length of each of a plurality of grid cells of the fluorescent grid.

6. The system of claim 1, wherein the grid drive mechanism is arranged outside the vacuum chamber; the grid drive mechanism comprises a linear actuator, a movable base, a sealing corrugated pipe and a connecting part;
the movable base is configured to reciprocate along a moving direction of the fluorescent grid under the drive of the linear actuator;
a first end of the sealing corrugated pipe is sealedly connected to the movable base, and a second end of the sealing corrugated pipe is sealedly connected to an outer wall of the vacuum chamber; and
a first end of the connecting part is connected to the fluorescent grid, and a second end of the connecting part is connected to the movable base; and a portion of the connecting part located outside the vacuum chamber is accommodated within the sealing corrugated pipe.

7. The system of claim 1, wherein the image acquiring unit is a Peltier-cooled charge coupled device (CCD) camera.

8. A method for measuring a three-dimensional vacuum magnetic field of the stellarator, the method being performed based on the system of claim 1, and the method comprising:
(S1) controlling the electron beam emission and adjusting unit to emit the electron beam from a preset emission position to a radial position located in the three-dimensional vacuum magnetic field of the stellarator;
(S2) adjusting an emission energy and a beam spot current of the electron beam to obtain a plurality of fluorescence images on the fluorescent grid under different parameter combinations; and selecting a parameter combination from the different parameter combinations as a target operation parameter based on brightness and definition of the plurality of fluorescence images, wherein the target operation parameter comprises a target emission energy and a target beam spot current;
(S3) controlling the electron beam emission and adjusting unit to emit the electron beam with the target operation parameter from the preset emission position to the radial position; controlling the grid drive mechanism to drive the fluorescent grid to periodically reciprocate at a preset speed; and controlling the image acquiring unit to perform the integration imaging with the exposure time that covers the at least one reciprocating cycle of the fluorescent grid, so as to obtain the magnetic surface trajectory image at the radial position; and
(S4) maintaining parameters of the three-dimensional vacuum magnetic field constant; controlling the electron beam emission and adjusting unit to move from the preset emission position along a radial direction of the three-dimensional vacuum magnetic field at a preset step size to a series of new radial positions; and repeating steps (S1-S3) at each of the series of new radial positions to obtain a plurality of magnetic surface trajectory images that are nested.

9. The method of claim 8, further comprising:
(S5) processing the plurality of magnetic surface trajectory images to extract central coordinates of a plurality of bright spots in each of the plurality of magnetic surface trajectory images, so as to reconstruct a measured magnetic surface profile of the three-dimensional vacuum magnetic field; and comparing the measured magnetic surface profile with a theoretical magnetic surface profile of the three-dimensional vacuum magnetic field at the same Poincaré surface of section.

10. The method of claim 8, wherein step (S1) further comprises:
adjusting the emission direction of the electron beam to minimize a Larmor radius thereof, so as to allow the electron beam to generate a fluorescence signal with a convergent, closed and clear trajectory on the fluorescent grid.
